(19) United States
(12) Patent Application Publication
(10) Pub. No.: US 2016/0060785 A1
(43) Pub. Date: Mar. 3, 2016

(54) Method to Fabricate Thin Film Solar Cell Absorbers with Roll-to-Roll Electroplating-Spraying Hybrid Apparatus

(71) Applicant: Jiaxiong Wang, Danville, CA (US)

(72) Inventor: Jiaxiong Wang, Danville, CA (US)

(21) Appl. No.: 14/474,176

(22) Filed: Aug. 31, 2014

(51) Int. Cl. C25D 17/02; H01L 31/032; H01L 31/18

(52) U.S. Cl. CPC C25D 17/02; H01L 31/1876; H01L 31/0322

(57) ABSTRACT

An electroplating-spraying hybrid apparatus that is assembled with modular electroplating sections in a roll-to-roll continuous electroplating and spraying process is provided. The length of the electroplating cell for a modular electroplating section is adjustable to fit different current densities and deposition thickness required in a roll-to-roll process. In addition, the electrolyte solution tanks can be simply connected or disconnected from the modular electroplating sections and moved away. With these designs, a multiple layers of coating with different metals or semiconductors can be electrodeposited through this apparatus with a flexibility to easily change the plating orders of different materials. Moreover, some dopant layers can be deposited with a spray pyrolysis method to coat materials that are not suitable for electroplating. This apparatus is particularly useful in manufacturing Group IB-IIIA-VIA and Group IIB-VIA thin film solar cells such as CIGS and CdTe absorbers on flexible substrates through a roll-to-roll process.

### BACKGROUND

1. Field of the Invention

The present invention relates to a method to fabricate thin film solar cell absorbers with roll-to-roll electroplating-spraying hybrid apparatus that is assembled with a series of modular electroplating sections and one or more spray pyrolysis sections to deposit multiple layers of metal and/or semiconductor thin films onto flexible substrates. In particular, it is a useful tool for fabricating thin film solar cells based on the Group IB-IIIA-VIA or IIB-VIA polycrystalline compounds.

2. Description of the Related Art

With the development of global warming, environmental contaminations and exhausting of fossil fuels, solar cells have attracted more and more attentions as a leading green energy source. Although crystalline silicon based solar cells still dominate the solar cell world market today, thin film solar cells have shown a very promising future due to their low costs, flexibility and capability of large-scale industrial manufacture. In this thin film solar cell family, the CIGS solar cells possess the highest conversion efficiency that is as high as 20%, higher than 16% efficiency of the CdTe ones. In the periodic table of the elements, the elements of a CIGS absorber are located in Group IB-IIIA-VIA and the ones of a CdTe absorber in Group IIB-VIA. Owing to their promising future, different techniques have been developed to fabricate these kinds of thin film solar cells. According to the materials and environments in the fabrications, these techniques can be roughly divided into dry and wet two groups. The dry methods are usually related to vacuum processes, such as physical vapor deposition (PVD) methods like sputtering, evaporation and sublimation, and chemical vapor deposition (CVD) methods. Although these dry methods have been well developed, some wet methods, such as spray, printing and electrochemical deposition, have been developed as well due to their low costs and simple procedures.

Among these wet processes, the spray and printing methods have been applied in manufacturing thin film solar cells. For example, NanoSolar developed a printing process to fabricate CIGS solar cells. This process has to prepare nanoparticles through complicated procedures and has to use some special procedures to concentrate CIGS nanoparticles compactly on the substrates. Otherwise, the films may become porous after the solvent is evaporated. An electrochemical deposition method plates metals from their salt electrolyte solutions onto some conductive or even non-conductive substrates with quantitatively controlled amounts and high quality of surface morphology. This non-vacuum procedure has a lot of advantages over those high-vacuum methods. For example, the surface morphology of a plated metal may be optimized with modification of a solution composition, and some micro-defects on the substrate surfaces may be filled up with the plated metals since the plating solution may fully soak onto the whole interior surfaces of those micro-channels. Driven with the Coulomb force, the metallic cations are attracted onto substrate surfaces and reduced to their atoms that are compactly aligned to form high quality of metallic films. Moreover, the electrodeposition methods can produce large area metallic films with uniform thickness that is still a big problem for most of high vacuum deposition. In addition to a single element, the electrochemical method can also be used to co-deposit multiple elements such as alloys that are homogeneous mixtures or solid solutions composed of two or more metals. Besides its advantages, an electrochemical method also possesses some disadvantages. For instance, the electroplated materials may be restricted by their reduction potentials and sensitive to some specific substrates due to the interaction among different materials. Moreover, a hydrogen evolution is always a problem in a cathodic electrodeposition. In spite of these disadvantages, the electroplating methods are still extensively used to deposit the CIGS films. For example, SoloPower has been successfully using electroplating methods to deposit CIGS absorbers. In particular, the different materials, such as copper, indium, gallium and selenium, can be co-deposited onto a conductive substrate to form a CIGS film. Although many investigations about the electrochemical co-deposition of CIGS films were published or patented, they are difficult to be applied in an industrial manufacture process due to a difficulty in controlling composition and uniformity of a plated CIGS film. Accordingly, the electroplating procedures to deposit a layer-by-layer CIGS film may be more practical to manufacture CIGS solar cells.

Both of CIGS and CdTe solar cells contain a stack of absorber/buffer thin film layers to create an efficient photovoltaic heterojunction. A metal oxide window containing a highly resistive layer, which has a band gap to transmit the sunlight to the absorber/buffer interface, and a lowly resistive layer to minimize the resistive losses and provide electric contacts, is deposited onto the absorber/buffer surface. This kind of design significantly reduces the charge carrier recombination in the window layer and/or in the window/buffer interface because most of the charge carrier generation and separation are localized within the absorber layer. In general, CIGS solar cell is a typical case in Group IB-IIIA-VIA compound semiconductors comprising some of the Group IB (Cu, Ag, Au), Group IIIA (B, Al, Ga, In, Tl) and Group VIA (O, S, Se, Te, Po) elements of the periodic table. In particular, compounds containing Cu, In, Ga, Se and S are generally referred to as CIGS(S), or Cu(In,Ga)(S,Se)₂ or CuIn₁₋ₓGaₓ (S_{y}Se_{1-y})ₙ, where 0≦x≦1, 0≦y≦1 and n is approximately 2, and have already been applied in the solar cell structures that gave rise to conversion efficiencies over 20%. It should be noted that although the chemical formula for CIGS(S) is often written as Cu(In,Ga)(S,Se)₂, a more accurate formula for the compound is Cu(In,Ga)(S,Se)ₙ, where n is typically close to 2 but may not be exactly 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1. Here, the molar ratios of Ga/(Ga+In) and Cu/(Ga+In) are very important factors to determine the compositions and the conversion efficiencies of the CIGS solar cells. In general, a good solar cell requires a ratio of Cu/(Ga+In) between 0.75 and 0.95, and Ga/(Ga+In) between 0.3 and 0.6. In comparison with CIGS, the composition of a CdTe solar cell is much simple. In general, the content of Cd is close to 50% in the CdTe films. However, the Cd content may change after the deposition of a CdS layer and the subsequent annealing procedure. Close to the interface of the p-n-junction, for example, a CdSₓTe₁₋ₓ layer is formed with x usually not exceeding 0.06. However, x has a range changing from 0 to 1, which results in a compound from CdTe (x=0) to CdS (x=1).

In a procedure of electroplating the CIGS absorbers with layer-by-layer manners, Cu, In, Ga and Se are plated onto the substrates with different orders to form various stacks, such as Cu/Ga/In/Se, Cu/In/Ga/Se, In/Cu/Ga/Se, Ga/Cu/In/Se, Cu/Se/In/Ga, In/Se/Cu/Ga, Cu/In/Se/Ga, and so on. The different metals can also be plated more than once to generate more multi-layer stack combinations such as Cu/In/Cu/Se/Ga, Cu/Ga/Cu/In/Se/Ga/In/Cu, Ga/Cu/In/Cu/In/Ga/Se/Cu/Se, and so on. Furthermore, the single elements can be combined with electroplated alloys to form various stacks like Ga—In/Cu/Ga/Se/In/Cu—Ga, Cu—In/Ga/Cu/Se/In/Ga/Se, Cu—Ga/In/Cu/Ga/Cu—Se/In/Se, etc. Similarly, a CdTe absorber can be stacked in a similar way but with a simpler combination due to fewer components. After the electroplating, these combined stacks have to be annealed with a temperature ramp up to a few hundred degrees to convert these multi-layer metallic materials into uniform p-type CIGS or CdTe semiconductor absorbers. On this CIGS semiconductor absorber, an n-type semiconductor buffer layer such as CdS, ZnS, or In₂S₃ should be deposited. By contrast, a CdTe absorber may require only CdS buffer layer. After then, transparent conductive oxide (TCO) materials, i.e., ZnO, SnO₂, and ITO (indium-tin-oxide), should be deposited to form the solar cells.

It has been found that trace sodium doping into a CIGS absorber layer or trace chlorine doping into a CdTe absorber layer may significantly increase efficiency of a CIGS or a CdTe thin film solar cell. To achieve this benefit, one may use vacuum deposition methods, such as evaporation or sputtering, to deposit a thin layer of sodium or chlorine salts into the CIGS or CdTe absorber layers. This may require additional vacuum equipment and significantly increase manufacture cost of a thin film solar cell. The deposition processes may be combined into another preparation procedure, such as co-evaporation of selenium and sodium salt layers in an evaporator. However, this significantly increases the complication and difficulty in preparation of the CIGS absorber layer since the evaporation temperatures for selenium and sodium salts are dramatically different. A wet process may not be suitable to deposit sodium or chlorine dopant layers because their salts are usually very soluble in solutions unless the freshly deposited dopant layers are immediately annealed with the absorber layers without washing or contacting any solutions.

Although the electroplating baths and methods of the CIGS and CdTe films have been well developed, the electroplating tools for industrial manufacture seem to be still in the traditional styles. In general, the electroplating of the substrates is carried out inside electroplating baths through piece-by-piece or bath-by-bath procedures. Continuous electroplating procedures have been developed as well. For example, Sergey Lopatin and David Eaglesham patented “Electroplating on Roll-to-Roll electroplating on Solar Cell Substrates” in 2008, and Bulent Basol also patented “Roll-to-Roll Electroplating for Photovoltaic Film Manufacture” in the same year. Moreover, some equipment companies of solar cells also produced some roll-to-roll electroplating production lines. However, all of these roll-to-roll electroplating apparatus are fixed to some pre-designed plating procedures. A manufacturer of such an electroplating production apparatus has to fabricate every electroplating section in a specific length according to its required current density and plated film thickness, and then assemble different electroplating sections together to form a continuous production line on the basis of the pre-designed electroplating orders to deposit different elements. As soon as it is setup, such an electroplating line is very difficult to change because dimensions of all the electroplating sections and connecting pipes have been fixed according to the pre-designed electroplating procedures.

As discussed in the previous paragraphs, the most successful industrially scaled electroplating of the CIGS thin films may be conducted with the multiple layers of single elements. In particular, the different plating orders of metal layers may produce totally different CIGS or CdTe absorbers after annealing. However, plating of different metals requires different plating conditions, especially various current densities that are determined by the electrochemical kinetics for a specific electroplating bath since most electroplating processes are carried out under constant currents. With an electroplating production line to deposit multiple metal layers for fabrication of a CIGS solar cell, for example, the required current densities for different layers may be ten times or even twenty times different. According to Faraday's Law of Electrolysis, a deposited film thickness is controlled by the applied current density and the reaction time for a plated metal or semiconductor layer. In a roll-to-roll electroplating apparatus, its width is fixed according to the width of a substrate roll. Since the delivery speed of the roll is pre-determined and the same for all of the electroplating sections, the length of every electroplating cell becomes the key variable to determine the reaction time and the film thickness under a certain current density. Here an electroplating cell means a closed structure to hold an electroplating solution and to equip with anodes in said solution. A flexible substrate roll can be continuously transported through this electroplating cell to complete an electroplating reaction. The length of an electroplating cell is defined to be a dimension along the moving direction of a flexible workpiece.

As described above, a pre-designed roll-to-roll multiple cell electroplating apparatus extremely restricts its application. If one develops a new copper bath requiring a high current density to replace the original solution that is used under a low current density, for instance, it may not be possible inside the original electroplating cell to remain the required copper thickness. Therefore, a new electroplating apparatus to plate multiple layers of metals and/or semiconductors for fabrication of CIGS or CdTe absorbers or other devices, with movable electrolyte solution tanks to store plating baths and adjustable electroplating cell lengths of which can be changed, is present. In addition to the electroplating function, the present apparatus includes a spray pyrolysis section at the end of the electroplating sections to deposit thin layers of sodium or chloride dopants without washing the freshly prepared dopant layers. Due to very thin films, the disadvantages of a spray or printing method for depositing thin films as mentioned above may not be significant in the present invention. With this electroplating-spray pyrolysis hybrid tool, not only can the plating baths and the plating orders of different metals be freely changed to meet different requirements of the applied current densities and plated film thickness, but also may the dopant layers easily be deposited without additional vacuum apparatus. Moreover, selenium may also be deposited with this spraying function to get rid of expensive vacuum equipment.

### SUMMARY OF THE INVENTION

The present invention provides a roll-to-roll electroplating-spraying hybrid apparatus to deposit multiple layers of different metals and/or semiconductors on thin continuous sheets of flexible substrates such as foils of stainless steels, aluminum, and polymer coils. This apparatus consists of a series of modular electroplating sections each of which includes a length-adjustable electroplating cell, a movable electrolyte solution tank, pumps, connection pipes and other accessories, plus a spray pyrolysis section to deposit some special dopant layers or even some main component. Every modular electroplating section possesses identical structure and dimension. The entire electroplating line can be flexibly assembled with a series of modular electroplating sections according to numbers of electroplating baths. Furthermore, the lengths of the electroplating cells can be readily adjusted to meet the requirements of different current densities determined by plating bathes and of plated film thickness. By assembling these modular electroplating sections together with some modular washing sections, drying unit, a spray pyrolysis section and unwinding/winding units, one can build up an electroplating apparatus to deposit multiple layers of metals and/or semiconductors. With this electroplating-spraying hybrid tool, different elements can be plated with changeable orders, and different current densities can be applied to any electroplating sections without changing skeleton of the apparatus. These advantages make this apparatus and this method particularly suitable to build up an R&D pilot line. The spray pyrolysis section can be used to deposit some materials that may not be suitable for electroplating. This electroplating-spraying hybrid apparatus is very useful for electroplating p-type semiconductive absorber layers in Group IB-IIIA-VIA and Group IIB-VIA thin film solar cells if the electroplating is carried out with a layer-by-layer manner. This apparatus can also be used as a general tool in various applications requiring layer-by-layer electroplating with different metals and/or semiconductors in a roll-to-roll process.

### BRIEF DESCRIPTION OF THE DRAWINGS

FIG. 1 shows a modular electroplating section in the apparatus to electroplate Group IB-IIIA-VIA or Group IIB-VIA absorber layers onto a flexible continuous substrate through a roll-to-roll process.

FIG. 2 is a 3D illustration to show the contour of an electroplating cell in a modular electroplating section.

FIG. 3 demonstrates a combination of an electroplating washing section, a drying unit and a spray pyrolysis section in the apparatus.

### DETAILED DESCRIPTION OF THE INVENTION

The present invention provides a production apparatus for electroplating multiple layers of metals and/or semiconductors onto flexible continuous substrates. In particular it is a useful tool for depositing Group IB-IIIA-VIA or Group IIB-VIA elements to form thin film solar cell precursor stacks, in a roll-to-roll process, for manufacturing CIGS or CdTe solar cell absorbers on flexible conductive or non-conductive substrates. The flexible conductive substrates may include foils selected from the materials consisting of stainless steel, aluminum, copper, molybdenum, nickel, zinc, and titanium with thickness between 0.02 and 0.2 millimeters and width from 0.05 to 2 meters. The flexible non-conductive substrates may be thin sheet workpieces of polymers, plastics, flexible ceramics and other thin films with thickness between 0.05 and 0.5 millimeters and width from 0.05 to 2 meters. Prior to use, these non-conductive coil surfaces shall be coated with one or more conductive layers such as different metals or semiconductors. The coated conductive layers are usually metals including but not restricted to molybdenum, chromium, tungsten, vanadium, niobium, tantalum, titanium, zirconium, hafnium, ruthenium, rhodium, copper, silver, gold, platinum, nickel, and iridium. The electroplated elements may be metals or semiconductors. An electroplated layer may be deposited as a pure element or an alloy film that contains two or more metals with a single phase or mixture of metallic phases. In particular, the present invention provides such an apparatus that is flexibly assembled with a series of modular electroplating sections. All of the electroplating sections are fabricated with the same dimensions and skeletons, but the length of an electroplating cell in every modular electroplating section can be adjusted to meet the special requirements of applied current densities and plated film thickness. In addition, the electrolyte solution tanks are movable. With these designs, this production apparatus is suitable for electrodepositing multiple layers of different metals, their alloys and/or semiconductors with changeable orders in a roll-to-roll process.

There are some restrictions for an electroplating method. For example, it cannot be used to electroplate soluble materials. It has been well known that doping of sodium salts into a CIGS absorber or chlorine element into a CdTe absorber may significantly increase efficiency of a CIGS or CdTe solar cell. Since sodium salts are usually soluble in water, it is not suitable to deposit them in a solution process for preparation of a CIGS absorber layer. Therefore, a sodium salt such as NaF is usually deposited through a dry process, i.e., a vacuum evaporation or a sputtering process. However, it wastes money to apply a roll-to-roll vacuum equipment to deposit trace amounts of materials. Therefore, it is popular for some CIGS manufacturers to deposit a sodium salt thin layer during a period of vacuum deposition of other materials such as selenium via a vacuum evaporation. Such a tactics may meet some other problems. In a vacuum evaporation, for instance, a temperature required to evaporate a sodium salt is much higher than selenium. A high temperature may affect the selenium deposition if the substrate is not cold enough during the process. It is also difficult to control and monitor the thickness and uniformity for such an extremely thin dopant layer in a roll-to-roll vacuum deposition process.

As a simple and inexpensive alternative of a vacuum process, a spray pyrolysis may be used to deposit a sodium salt and/or even selenium although it is a kind of wet deposition method. As a very simple embodiment, an alcohol or aqueous solution containing sodium and selenium may be prepared as a mother liquid. The solution is sprayed through a commercial ultrasonic spray nozzle that is designed for a roll-to-roll process onto a substrate surface coated with multiple layers of copper, gallium, indium, and/or selenium materials through an electroplating process. An ultrasonic spray nozzle helps to distribute the solution into very tiny mist. Compressed air can be used surrounding the spray nozzle to form a skirt for a purpose of uniformity control. The travelling substrate roll is heated with one or more heating modules installed underneath the substrate. The solvent with a low boiling point will be immediately evaporated and leave a dry deposited film on the substrate surface. Although the solvent evaporation may leave some holes in the spray deposited thin layer, it may not exert any significant influence for preparation of an absorber layer because the dopant layer is very thin. Then the roll can go to the following procedures such as more selenium evaporation and annealing. In addition, selenium can also be spray deposited to totally get rid of a vacuum coating process without significantly affect the quality of a CIGS or CdTe absorber layer.

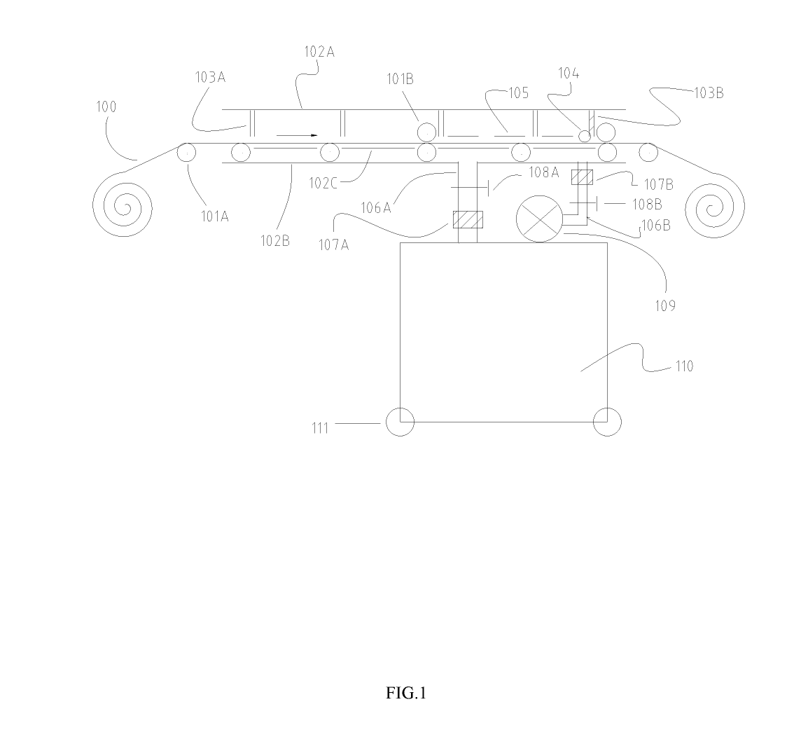

FIG. 1 shows an embodiment of a modular electroplating section in said apparatus. The main body of a whole apparatus can be assembled with multiple modular electroplating sections. Between every two modular electroplating sections, one modular washing section shall be inserted. This washing section contains nozzles to wash both sides of the flexible continuous thin sheet workpieces to make sure that a clean surface is brought into the next modular electroplating section. There are also some electrically conductive rollers or brushes mounted inside the washing sections to conduct cathodic current to the moving workpieces. For a roll of flexible conductive substrate, these conductive rollers or brushes, made of metallic materials or non-metallic materials such as carbon or conductive ceramics, can be arranged underneath the substrate to contact its backside. For a non-conductive flexible substrate coil, however, the electrically conductive rollers or brushes have to be installed to contact top surface edges of the workpiece. At the end of the electrodeposition, the substrate will be further washed and dried. For drying of a completed flexible workpiece, one or more drying units have to be attached close to the end of this electroplating apparatus. The whole electroplating apparatus has to include a unwinding unit and a winding unit to transport the workpiece rolls. From the unwinding unit to the winding unit, the whole roll is horizontally delivered through different modular electroplating sections, modular washing sections and dry units without bending the substrate within this process. If a user wants to monitor thickness of plated materials, a measurement device such as an XRF analyzer can be inserted in front of the winding unit. One or more spray pyrolysis sections can be inserted between the dry unit and the winding unit to spray the dopant layers.

According to the embodiment of the invention as shown in FIG. 1, a modular electroplating section includes a top edge 102A formed from top edges of two parallelly arranged vertical sidewalls that possess the same length, a base 102B horizontally mounted to bottom edges of said vertical sidewalls, a bottom 102C horizontally mounted to lower internal surfaces of said two vertical sidewalls, two or more lower rollers 101A mounted above said base for transporting a flexible continuous substrate 100 above said bottom, two or more pairs of vertical grooves 103A cut into both internal surfaces of said two vertical sidewalls for holding a movable isolating board below said top edge 102A, and a fixed isolating board 103B vertically mounted close to one said sidewalls' end that is closer to the winding unit than the other end and the movable isolating board. In this way, two said vertical sidewalls, said bottom 102C, said movable vertical isolating board connected one of pairs of grooves 103A, and said fixed isolating board 103B constitute a container that introduces an electrolyte solution through a pipe 104 and elutes said electrolyte solution through slots on the bottom 102C around the rollers 101A. This container is called as an electroplating cell where the elements are electrodeposited onto the surface of a moving flexible substrate.

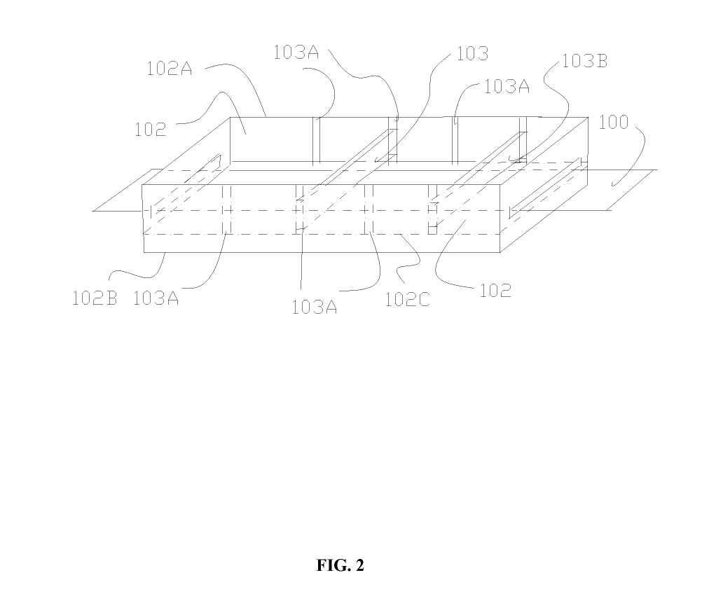

A contour of said electroplating cell is illustrated in FIG. 2. In this 3D drawing, some parts, such as rollers, pipes and anodes, are ignored in order to emphasize the relationship among said vertical sidewalls, said isolating boards, said base and said bottom. FIG. 2 illustrates four pairs of vertical grooves 103A cut into both internal surfaces of said two vertical sidewalls 102, wherein a fixed isolating board 103B is inserted into the rightmost pair of vertical grooves and a movable isolating board 103 is inserted into one of rest three pairs of said vertical grooves 103A to constitute an electroplating cell. By inserting the left movable isolating board 103 to different pairs of said grooves 103A, one can simply change the length of an electroplating cell to meet different requirements of applied current densities and thickness of a plated layer. Outside said electroplating cell, two or more top soft squeezing rollers 101B not shown in FIG. 2) are arranged beside the movable isolating board 103 and fixed isolating board 103B. These top soft squeezing rollers 101B, probably made of silicone, EPDM (Ethylene Propylene Diene Monomer) or SBR (Styrene Butadiene Rubber), sit above the moving substrate with self-weights to avoid scratching and damaging the plated layers, and form a barrier for preventing the electrolyte solution from flowing out of said electroplating cell. These top soft squeezing rollers have to be placed inside the modular washing sections as well to preventing the washing solution from flowing back into the electroplating cells. Inside said electroplating cell, one or more net anode modules 105 can be attached parallel above to the flexible substrate. The means to hold these net anode modules may be some metallic frames, i.e., titanium frame probably coated with iridium oxide. A longer electroplating cell requires more anode modules. These chemical resistant net anode modules are porous to allow the gas escaping from the plating baths. Since the substrates are facing up, any gas bubbles from the cathodic side reactions will escape immediately from the substrate surface during electroplating to avoid gas bubbles and defects left in the plated films. The net anode modules may be made of titanium coated by iridium or ruthenium oxides. The electroplating cell may have a length ranging from 0.1 to 2 meters and a width ranging from 0.1 to 2 meters. Here the length stands for a distance between movable and fixed isolating boards along the substrate moving direction, and the width represents a distance between the internal surfaces of two vertical sidewalls 102.

In one aspect of the embodiment, the modular electroplating section further includes an external cell constituted from said two vertical sidewalls 102, the base 102B and two vertical end walls (as shown in FIG. 2) mounted to left and right ends of said two vertical sidewalls 102, respectively.

In another aspect of the modular electroplating section, the means for introducing an electrolyte solution into said electroplating cell includes one or more dead end pipes 104 connected to pipes 106B, one or more valves 108B, one or more quick connect/disconnect pipe couplings 107B, and one or more pumps 109 installed on the top of a electrolyte solution tank 110 that stores the electrolyte solution for plating. Too much solution pumped up into the electroplating cell will flow through slots in the bottom 102C and overflow from the corner of the fixed isolating board and/or a slot cut on the back vertical sidewall into the external cell for eluting back to the electrolyte solution tanks 110. The means for eluting the electrolyte solution may include one or more pipes 106A, one or more valves 108A, and one or more quick connect/disconnect pipe couplings 107A. The modular electroplating section includes one or more movable electrolyte solution tanks 110 with two or more wheels front of which can revolve 360 degree for freely changing moving directions. The whole production apparatus may include one or more of the modular electroplating sections and other components such as modular washing sections. A modular washing section may have a similar structure to the electroplating section. For example, it may have one or more deionized water tanks equipped with one or more pumps to deliver water up to a washing cell where the water is sprayed out to wash both top and bottom surfaces of the flexible substrate. Thus, the modular electroplating section is adapted to be assembled into a production apparatus, for example, by having hookups for assembling with other sections and units.

In another embodiment, a method of fabricating CIGS or CdTe thin film solar cells by electroplating multilayer CIGS or CdTe absorber stacks is provided. The method includes to apply cathodic currents to a flexible substrate transported through an electroplating apparatus including one or more modular electroplating sections for depositing one or more layers of metals, metallic alloys and/or semiconductors onto a flexible continuous workpiece via a roll-to-roll process, and plate different elements or their alloys in changeable orders through said electroplating apparatus, wherein said modular electroplating sections include adjustable lengths of the electroplating cells and movable electrolyte solution tanks. Here, the metals, metallic alloys and/or semiconductors for electroplating include elements selected from Group IB-IIIA-VIA or Group IIB-VIA such as Cu, In, Ga, Se, Cd, and Te.

As shown in FIG. 1, a flexible conductive substrate 100 is delivered into a modular electroplating section from left to right along the arrow direction. The rollers 101A are arranged under the substrate to support it and the soft squeezing rollers 101B sit on the top of the substrate just outside of the electroplating cell to prevent the electrolyte solution from flowing out without damaging the plated layers. 102A and 102B represent the top edge and the base of the modular electroplating section. 102C is the bottom of the electroplating cell. It is a few centimeters under the substrate 100. 103B is a fixed isolating board to form the right wall of the electroplating cell. 103A stands for several pairs of grooves cut into the internal surfaces of both vertical sidewalls of the modular electroplating section. Between a pair of grooves, a movable isolating board 103 can be tightly inserted to hold the solution inside the electroplating cell between 103B and 103. By placing this movable isolating board 103 to the other pairs of grooves 103A, one can adjust the length of the electroplating cell to meet requirements of the applied current densities and the thickness of a plated layer. Inside the electroplating cell, the net anode modules 105 can be fixed parallel above to the flexible substrate. A longer electroplating cell requires more anode modules. These chemical resistant net anode modules are porous to allow the gas escaping from the plating baths. There is a pipe 104 with a dead end on one side and some small holes on the body. The other open end of this pipe is connected to the pipe 106B through a quick connect/disconnect pipe coupling 107B. The electrolyte solution shall be delivered with the pump 109 from the solution tank 110 up to the pipe 104, and then flowing back to the tank through the pipe 106A. The hole diameters, density and arrangement in the pipe 104 shall be carefully designed to meet the requirements of electroplating hydrodynamics. Two valves 108A and 108B are used along with the pump 109 to hold enough solution inside the electroplating cell. A filter (not shown in FIG. 1) can be installed between the valve 108B and the pump 109 or another location to filter the plating solution. A better design is to attach another pump to the solution tank 110 for circulating the electrolyte solution through a filter. The solution tank 110 may be easily connected and disconnected from said modular electroplating section with quick connect/disconnect pipe couplings 107A and 107B and moved away through two or more wheels 111 installed under the bottom of the tank.

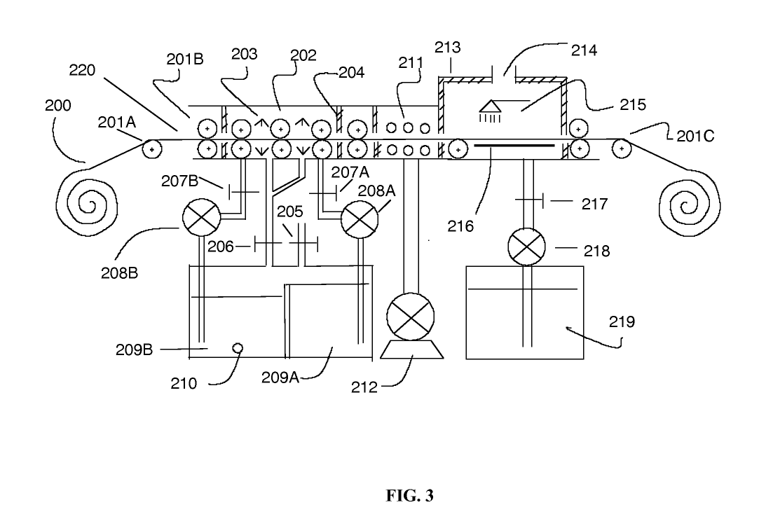

According to the embodiment demonstrated in FIG. 3, a modular washing section contains a washing compartment 202, two groups of water spray nozzles 203, a pairs of pumps 208A and 208B, a water tank, etc. Next to this washing section, there is a substrate-drying unit where two groups of heating pipes 211, made from some metals such as stainless steel, aluminum, titanium or copper, are arranged above and below the substrate 200 to dry it with compressed hot air streams out of some holes in the pipes and delivered from a hot air blower 212. Here the hot air heating system can be replaced by other heating components, such as infrared (IR) or ultraviolet (UV) lamps. One or more spray pyrolysis sections 213 with an evacuation vent 214 are assembled next to the drying unit. One or more heating modules 216 composed of heating elements and thermocouples are installed underneath the substrate. The power of each heating module can be adjusted according to the boiling points of solvents and the temperature can be precisely controlled and monitored with the thermocouple. The length of a spray pyrolysis section can be designed according to the substrate delivery speed and one or more ultrasonic spray nozzles 215 are installed above the substrate 200. The sprayed solution is delivered through a continuous low-flow metering or gear pump 218 from a solution tank 219 to the spray nozzle 215. A valve 217 is arranged to control solution flowing. The spray nozzle 215 is connected to an ultrasonic atomizer (not drawn here) to generate very tiny droplets. Compressed air may be used surrounding the spray nozzles as a wind skirt to control the spray directions.

When a substrate roll 200 completes its electroplating deposition and enters the final washing compartment 202 (220 represents a location connected to the electroplating sections), as illustrated in FIG. 3, it is washed by two groups of water nozzles 203 installed above and below the substrate. Rollers 201A represent some rollers to support the substrate roll, and rollers 201B are soft squeezing rollers above the substrate to prevent water out of the washing compartment. Some isolating boards 204 separate different compartments. The substrate 200 is washed twice in two sub-sections isolated with a pair of rollers 201A and 201B. The second washing is carried out with fresh water, which is introduced through a valve 205 into compartment 209A in the water tank and then pumped up to the water nozzles with a pump 208A and controlled via a valve 207A. The used water flows through a valve 206 back to compartment 209B in the water tank. This used water is pumped up through a pump 208B and a valve 207B to the first group of water nozzles inside the washing compartment 202. The used water will flow back through the valve 206 as well. The used water inside the compartment 209B can be recycled or discarded through an outlet 210. The fresh water inside the compartment 209A can overflow into the compartment 209B. With these designs, lots of water can be saved. The cleaned substrate then travels into the drying unit.

The cleaned and dried substrate coated with electroplated multiple layer stacks of CIGS raw materials can be deposited with dopant thin layers or some main component such as selenium inside the spray pyrolysis section 213, as described above. The completed substrate can be directly delivered through a deviation controlling roller 201C into the winding unit.

With this equipment, a process to fabricate thin film solar cell absorbers through multiple said electroplating sections and said spray section can be summarized as following: 1) decide an electroplating order to deposit different layers and adjust every length of said electroplating cells; 2) load a roll of flexible workpiece into said unwinding unit and release this substrate roll through different sections to said winding unit; 3) install all of said anodes, rollers, pipes and get the whole system ready (such as solution circulation, cooling, washing, drying, monitoring, etc.); 4) start to wind said workpiece roll and pump the electroplating solutions up into said electroplating cells; 5) from the first to last electroplating cells, apply current with different strengths to each pairs of anodes and cathodes to deposit thin layers of metals, metallic alloys and/or semiconductors; 6) wash electroplated layers in said washing sections after every plating; 7) dry the substrate surface before the plated workpiece enter said spray section; 8) start to spray said dopant layer onto the electroplated roll surface; and 9) stop work with a reverse order of starting work and collect completed workpiece roll.

### Example 1

### Electroplating of a Copper Layer onto a Molybdenum Surface Coated on a Stainless Steel Roll at a High Current Density

A one-foot wide stainless steel roll coated with a molybdenum layer was loaded to the unwinding unit. It was transported from left to right through an electroplating modular section as shown in FIG. 1 at a speed of 1 meter per minute. An aqueous electroplating copper solution containing 0.1 M Cu² in 6% H₂SO₄ was loaded into the tank 110, delivered into the electroplating cell through the pump 109, the pipe 106B and the pipe 104, and then flowing back to the tank through the pipe 106A. To plate Cu at a high current density, a vertical isolating board was inserted into a pair of vertical grooves 103A that is close to the right wall 103B to build a short electroplating cell that might contain only one piece of the net anode module 105. One pair of soft squeezing rollers 101B were put outside the left and the right of the electroplating cell to prevent the solution from flowing out of the electroplating cell. On the purpose of reducing gas generation and remain the Cu²⁺ concentration in the bath, a piece of pure copper lump was put on the top of the net anode module. This set-up remains the plating electrolyte solution inside the electroplating cell and submerges the copper lump very well. A constant current of 25 A was applied onto this modular electroplating section to plate about 100 nanometer thick Cu layer onto the Mo surface. The film looks nice and no much gas bubbles were generated during the plating due to application of the soluble anode.

### Example 2

### Electroplating of a Copper Layer onto a Molybdenum Surface Coated on a Stainless Steel Roll at a Low Current Density

The same substrate as Example 1 was used in this example. An aqueous electroplating copper solution containing 0.1 M Cu²⁺ in 0.5 M EDTA with a pH about 10 was loaded into the tank 110, delivered into the electroplating cell through the pump 109, the pipe 106B and the pipe 104, and then flowing back to the tank through the pipe 106A. This electroplating bath prefers a low current density to obtain a thin copper film with a good quality. To meet the requirements for a low plating current density and the same film thickness of 100 nanometers, the length of the electroplating cell was increased by inserting a movable isolating board 103 a pair of vertical grooves 103A far away from the right fixed isolating board 103B. Four pieces of the net anode modules 105 were attached. No copper piece was used as a soluble anode in this case. The substrate delivery speed and the applied constant current were the same as described in Example 1. Since the electroplating cell length was a few times longer than the one in Example 1, however, the plating was carried out at a much lower current density. The plated copper layer looked shining and uniform.

### Example 3

### Spray Pyrolysis to Deposit Thin Selenium Layer Containing Sodium Dopants onto an Electroplated CIG Substrate

The spraying precursor solution was prepared by dissolving Na₂SeSO₃ in HCl to form a colloid solution that was sprayed through a set of Sono-Tek wide area spray system onto a one-foot wide roll 200 of stainless steel substrate coated with electroplated Cu, Ga and In precursor multiple layers. A single nozzle 215 was used to provide ultrasonically atomized spray that is shaped and directed toward the travelling substrate by precisely timed jets of air (or nitrogen). The temperature of heating modules 216 was set over 250° C. to make the surface temperature of the substrate close to 200° C. At this temperature, the sprayed precursor solution decomposed on the heated substrate to generate Se nanoparticles, NaCl dopant, SO₃ and water. The water and SO₃ were evaporated immediately from the substrate surface and an orange color layer of Se and NaCl mixture was deposited on the substrate surface. The spray was carried out inside the sealed cabinet 213 and the evaporated waste was evacuated from the evacuation vent 214. The film thickness could be controlled at about 100 nanometers (nm). The completed roll shall be deposited with more excess Se from an evaporator.

### Example 4

### Spray Pyrolysis to Deposit Thick Selenium Layer Containing Trace Amounts of Sodium Dopants onto an Electroplated CIG Substrate

Two rows of ultrasonic nozzles were installed inside the spray compartment. Before spraying the Se precursor solution, a diluted sodium chloride (NaCl) or sodium fluoride (NaF) was firstly sprayed onto the substrate using the first row of ultrasonic nozzles. The Se precursor solution was prepared as two mother liquids: selenious acid (H₂SeO₃) and hydrazine mixed with diluted HCl. The preparation procedures of these two mother liquids were slightly complicated. Two mother liquids were mixed and sprayed through the second row of Sono-Tek spray nozzles to deposit this Se film. The dual nozzles 215 were used to provide ultrasonically atomized spraying, which is shaped and directed toward the travelling substrate by precisely timed jets of nitrogen. The temperature of heating modules 216 was set to about 250° C. to make the surface temperature of the substrate close to 200° C. At this temperature, Se was deposited to the substrate surface and the other side products including N₂, HCl and H₂O were evaporated immediately from the substrate surface according to the following chemical reaction:

H₂SeO₃+N₂H₄2(HCl)→Se↓+N₂↑+3H₂O↑+2HCl↑

The spray pyrolysis was carried out inside the sealed cabinet 213 and the evaporated waste was evacuated from the evacuation vent 214. A roll of one-meter wide stainless steel substrate 200 coated with electroplated Cu, Ga and In multiple precursor layers was used. The film thickness could be controlled up to 2 micrometers (μm) covering previously sprayed about 1% of uniformly distributed Na dopant.

It is not necessary to use any expensive vacuum tool for deposition of Se and Na dopant in this example. Although the spray deposited Se layer is porous, it does not affect the quality of the final CIGS absorber as described below. After going through this electroplating-spraying hybrid apparatus, a substrate roll has been deposited not only with stoichiometric amounts of Cu, Ga and In, but also with excess amounts of Se and desired Na dopant. The next step will be annealing of the CIGS precursor to obtain a stoichiometric CIGS absorber. The annealing temperature inside a thermal reactor shall be set between 400 and 600° C. At this temperature range, the top Se layer with a melting point 221° C. shall totally melt in the initial rapid temperature process (RTP). Some Se evaporates, and some reacts with Cu, Ga and In to form a stoichiometric CIGS absorber. Because the electroplated Cu, Ga and In multiple stacks are compact, the porous sprayed Se layer on the top does not generate additional holes inside the CIGS precursor layer since it becomes liquid at the beginning of the annealing process.

As described above, this electroplating-spraying hybrid apparatus has been manufactured to deposit Group IB-IIIA-VIA or Group IIB-VIA solar cell absorber stacks onto the flexible continuous substrates with different widths. With the present invention, one can totally get rid of very expensive vacuum deposition equipment to prepare a CIGS or CdTe semiconductive absorber layer in manufacture of thin film solar cells. It also makes the fabrication process of an absorber layer much simple. It can also be used to electrodeposit multiple layers of different metal or semiconductor stacks through a roll-to-roll or reel-to-reel process in other applications.

I claim:

1. A method to fabricate semiconductive absorbers of CIGS or CdTe thin film solar cells, via an electroplating-spraying hybrid apparatus comprising: one or more modular electroplating sections, one or more modular washing sections, one or more drying units, one or more spray pyrolysis sections, one unwinding unit to release a substrate roll and one winding unit to collect the electroplated and/or sprayed substrate, to deposit one or more layers of metals, metallic alloys and/or semiconductors onto a flexible continuous substrate via a roll-to-roll process, includes following steps: load said substrate into said unwinding unit, deliver said substrate through said electroplating sections to deposit said layers of metals, metallic alloys and/or semiconductors and through said washing sections to clean said electroplated layers, dry electroplated layers through said drying units, and/or spray dopant layers through said spray pyrolysis sections, and finally collect said substrate in said winding unit.

2. The method of claim 1 including: one or more steps of electroplating processes carried out firstly to deposit one or more layers of said metals, metallic alloys and/or semiconductors; and one or more spray pyrolysis processes conducted then onto a dried flexible substrate coated with electroplated layers to deposit one or more dopant layers and/or one or more main components.

3. The method of claim 2 wherein said metals and semiconductors are one or more elements selected from Group IB, IIIA and VIA respectively, or one or more elements selected from Group IIB and VIA respectively; and wherein the order to electroplate different layers of materials is changeable.

4. (canceled)

5. The modular electroplating section recited in claim 1 comprising: one or more electroplating cells with adjustable lengths along the substrate moving direction ranging from 0.1 to 2 meters and width ranging from 0.1 to 2 meters; one or more movable electrolyte solution tanks with two or more wheels; one or more pumps to pump electrolyte solution up; and one or more connect/disconnect pipe couplings between said electroplating cells and said movable electrolyte solution tank.

6. The electroplating cell recited in claim 5 comprising: two or more parallelly arranged vertical sidewalls with the same length; a base horizontally mounted to bottom edges of said vertical sidewalls; a cell bottom horizontally mounted to lower internal surfaces of said vertical sidewalls; one or more isolating boards perpendicularly and vertically fixed close to one end of said vertical sidewalls; and one or more movable isolating boards perpendicularly and vertically mounted to the other side of said vertical sidewalls.

7. The electroplating cell of claim 6, wherein said vertical sidewalls possess one or more pairs of vertical grooves cut into their internal surfaces; and length of said electroplating cell is adjustable by inserting said movable isolating board into different pairs of said vertical grooves.

8. The apparatus used in claim 1 wherein the entire length of said apparatus is changeable by adding or reducing numbers of said identical modular electroplating sections.
